(19) United States
(12) Patent Application Publication
(10) Pub. No.: US 2010/0052161 A1
(43) Pub. Date: Mar. 4, 2010

(54) Semiconductor wafer with adhesive protection layer

(75) Inventor: Shiann-Tsong Tsai, Hsinchu (TW)

Correspondence Address: EDWARDS ANGELL PALMER & DODGE LLP, P.O. BOX 55874, BOSTON, MA, 02205, US

(73) Assignee: UTAC(Taiwan) Corporation, Hsin-Chu (TW)

(21) Appl. No.: 12/315,788

(22) Filed: Dec. 4, 2008

(30) Foreign Application Priority Data
Sep. 3, 2008 (TW) 097133690

(51) Int. Cl. H01L 23/498

(52) U.S. Cl. 257/737; 257/E23.068

(57) ABSTRACT

A semiconductor wafer with an adhesive protection layer includes: a wafer body having a first surface and an opposing second surface; a plurality of electrical connection pads formed on the second surface of the wafer body; and the adhesive protection layer formed on the second surface of the wafer body and the plurality of electrical connection pads, wherein the protection layer is made of a material including a photosensitive adhesive, a thermal-setting adhesive and a dielectric material. The protection layer not only isolates circuits on the wafer surface from external moisture and contaminant, but also can be patterned and is adhesive, such that the wafer can be mounted to a circuit substrate in a subsequent process by the protection layer, without having to apply an additional adhesive on the wafer, thereby greatly simplifying the wafer-substrate attachment procedure during package fabrication processes.

### FIELD OF THE INVENTION

The present invention relates to semiconductor wafers, and more particularly, to a semiconductor wafer with an adhesive protection layer.

### BACKGROUND OF THE INVENTION

Semiconductor fabrication processes usually start from fabricating semiconductor wafers by, for example, lamination, patterning, doping and thermal treatment. When the semiconductor wafers are fabricated, they undergo additional processes, such as testing, packaging and chip assembling. During the chip packaging stage for forming a leadframe-based package or a ball grid array (BGA) package, a chip must be attached to a package substrate by means of an additional adhesive, and then can be electrically connected to the package substrate via bonding wires.

To fabricate a window-type BGA package, for example, an adhesive layer is applied on a surface of the chip or package substrate, for attaching the chip to the package substrate. In such case, an additional process is required to form at least an opening in the adhesive layer in order to expose electrical connection pads of the chip. As the adhesive layer is interposed between the chip and the package substrate, two interfaces are formed: one is between the adhesive layer and a covering layer of the chip, and the other is between the adhesive layer and the package substrate. Due to different materials constituting the layers forming the interfaces, delamination easily occurs between the chip and the adhesive layer or between the adhesive layer and the package substrate, thereby undesirably degrading the fabrication yield.

Therefore, the problem to be solved here is to develop a semiconductor wafer or chip, which allows the wafer-substrate attaching process to be simplified and avoids delamination between the attached layers.

### SUMMARY OF THE INVENTION

In view of the drawbacks in the prior art, an objective of the present invention is to provide a semiconductor wafer with an adhesive protection layer, which can simplify the fabrication processes and reduce the fabrication cost.

Another objective of the present invention is to provide a semiconductor wafer with an adhesive protection layer, wherein the adhesive protection layer can protect circuits and electrical connection pads formed on a surface of the wafer.

In accordance with the above and other objectives, the present invention proposes a semiconductor wafer with an adhesive protection layer, comprising: a wafer body having a first surface and an opposing second surface; a plurality of electrical connection pads formed on the second surface of the wafer body; and the adhesive protection layer formed on the second surface of the wafer body and the plurality of electrical connection pads, wherein the protection layer is made of a material comprising a photosensitive adhesive, a thermal-setting adhesive and a dielectric material, and allows the semiconductor wafer being singulated to be mounted to a package carrier.

The present invention also proposes another semiconductor wafer with an adhesive protection layer, comprising: a wafer body having a first surface and an opposing second surface; a plurality of electrical connection pads formed on the first and second surfaces of the wafer body; and the adhesive protection layer formed on the plurality of electrical connection pads and each of the first and second surfaces of the wafer body, wherein the protection layer is made of a material comprising a photosensitive adhesive, a thermal-setting adhesive and a dielectric material, and allows the semiconductor wafer being singulated to be mounted to a package carrier.

Therefore, with the semiconductor wafer of the present invention, the protection layer isolates circuits on the wafer surface from external moisture and contaminant, and the protection layer is adhesive to allow the wafer to be mounted to a circuit substrate in a subsequent process without having to apply an additional adhesive on the wafer, thereby greatly simplifying the wafer-substrate attachment procedure during package fabrication processes and desirably reducing the fabrication cost.

### BRIEF DESCRIPTION OF THE DRAWINGS

FIG. 1 is a cross-sectional schematic diagram showing a semiconductor wafer with an adhesive protection layer according to an embodiment of the present invention;

FIG. 2 is a cross-sectional schematic diagram showing a semiconductor wafer with an adhesive protection layer according to another embodiment of the present invention;

FIGS. 3A to 3E are cross-sectional schematic diagrams respectively showing a semiconductor wafer with an adhesive protection layer having openings according to various embodiments of the present invention;

FIG. 3F is a cross-sectional schematic diagram showing the semiconductor wafer with an adhesive protection layer according to the present invention mounted on a package carrier;

FIG. 4 is a cross-sectional schematic diagram showing a semiconductor wafer with an adhesive protection layer having openings according to another embodiment of the present invention; and

FIGS. 5A and 5B are cross-sectional schematic diagrams respectively showing a semiconductor wafer with an adhesive protection layer and conductive bumps according to the present invention.

### DETAILED DESCRIPTION OF THE PREFERRED EMBODIMENTS

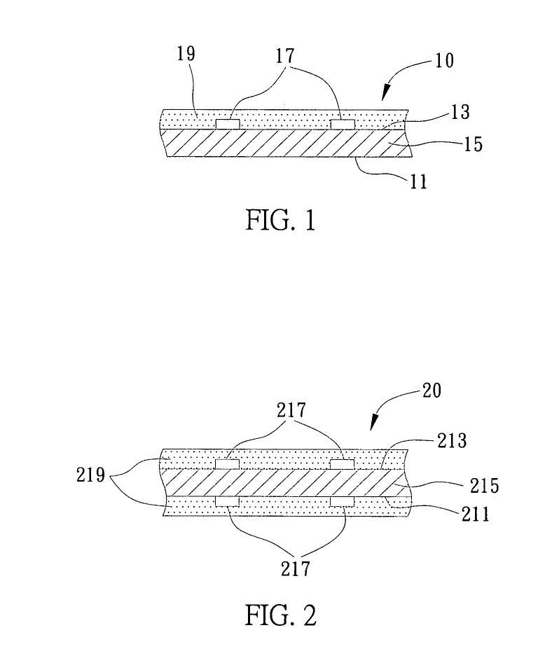

Preferred embodiments of a semiconductor wafer with an adhesive protection layer proposed in the present invention are described as follows with reference to FIGS. 1, 2, 3A to 3F, 4, 5A and 5B. It should be understood that the drawings are schematic diagrams only showing relevant components in the present invention, and the practical component layout could be more complicated.

In order to achieve the objectives of the present invention, a method for fabricating a semiconductor wafer with an adhesive protection layer is provided, comprising the steps of: providing a wafer body with predetermined circuit layouts and a plurality of electrical connection pads being formed on surfaces thereof; and forming a protection layer on at least one of the surfaces of the wafer body, wherein the protection layer comprises a photosensitive adhesive, a thermal-setting adhesive and a dielectric material. In this embodiment, as the protection layer comprises the photosensitive adhesive, exposure and development processes can be optionally performed on the protection layer so as to expose the electrical connection pads on the wafer body and allow the electrical connection pads to be electrically connected to a package substrate by bonding wires.

The present invention also provides another method for fabricating a semiconductor wafer with an adhesive protection layer, comprising the steps of: providing a wafer body with predetermined circuit layouts being formed on surfaces thereof; forming a protection layer on at least one of the surfaces of the wafer body, wherein the protection layer comprises a photosensitive adhesive, a thermal-setting adhesive and a dielectric material; then, performing exposure and development processes on the protection layer by a conventional technique to form a plurality of openings in the protection layer for partially exposing the circuit layouts on the wafer body; forming a plurality of electrical connection pads in the openings of the protection layer; and optionally, on the protection layer and the electrical connection pads, forming another protection layer proposed in the present invention.

As the protection layer of the present invention comprises the photosensitive adhesive, the adhesion between the protective layer and the wafer body is further enhanced when the exposure and development processes are completed. In the present invention, the protection layer can be firstly subjected to exposure to have the photosensitive adhesive exposed and developed, and then the exposure and development processes are continued until completion; optionally, the protection layer can further be irradiated to allow the photosensitive adhesive to be fully cured (i.e. c-stage). Alternatively, as the protection layer of the present invention further comprises the thermal-setting adhesive, the protection layer can be optionally subjected to thermal treatment in any stage so as to allow the thermal-setting adhesive to become a partially cured (i.e. b-stage) adhesive or allow the entire protection layer to become b-stage, thereby further enhancing the adhesion of the protection layer. It is also understood that, the protection layer can undergo both irradiation and thermal treatment, making the entire protection layer become b-stage. Moreover, the protection layer of the present invention comprises the dielectric material that is relatively compatible with the wafer body or package substrate, thereby enhancing the bonding strength between the protection layer and the wafer body or package substrate to a certain extent.

The term “partially cured” or “b-stage” used herein means that a conversion rate of a material or an adhesive does not reach 80% to 100%. Preferably, the conversion rate is 35 % to 80%, which means that, for example, 35% to 80% of cross-linkable functional groups in a compound undergo a cross-linking reaction, making the material or adhesive have adhesion. The expression “the entire protection layer (to) become b-stage” means that 35% to 80% of cross-linkable functional groups contained in the protection layer undergo a cross-linking reaction. The term “fully cured” or “c-stage” used herein refers to the conversion rate of the material or adhesive reaching 80% to 100%. Preferably, the conversion rate is 90% to 100%.

FIG. 1 is a cross-sectional schematic diagram showing a semiconductor wafer with an adhesive protection layer according to an embodiment of the present invention. As shown in FIG. 1, the semiconductor wafer 10 comprises: a wafer body 15 having a first surface 11 and an opposing second surface 13; a plurality of electrical connection pads 17 formed on the second surface 13 of the wafer body 15; and a protection layer 19 formed on the plurality of electrical connection pads 17 and the second surface 13 of the wafer body 15. The protection layer 19 is made of a material comprising a photosensitive adhesive, a thermal-setting adhesive and a dielectric material.

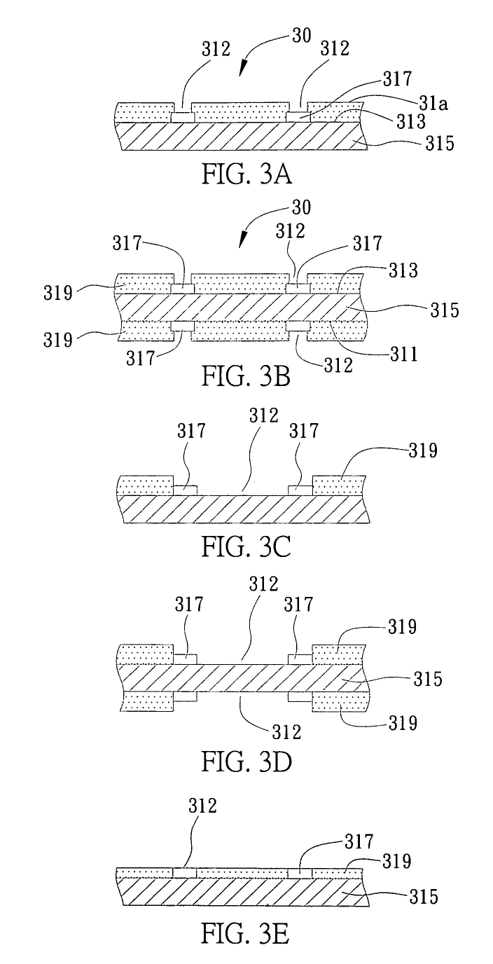

FIG. 2 is a cross-sectional schematic diagram showing a semiconductor wafer with an adhesive protection layer according to another embodiment of the present invention. As shown in FIG. 2, this semiconductor wafer 20 comprises: a wafer body 215 having a first surface 211 and an opposing second surface 213; a plurality of electrical connection pads 217 formed on the first and second surfaces 211, 213 of the wafer body 215; and a protection layer 219 formed on the plurality of electrical connection pads 217 and each of the first and second surfaces 211, 213 of the wafer body 215. The protection layer 219 is made of a material comprising a photosensitive adhesive, a thermal-setting adhesive and a dielectric material. In these embodiments, the semiconductor wafer with an adhesive protection layer can be fabricated by the method described above.

In the present invention, the electrical connection pads are made of, for example (but not limited to), aluminum or copper; any other suitable conductive metallic material can also be used. The material of the protection layer in the present invention comprises, but not limited to, a photosensitive adhesive, a thermal-setting adhesive and a dielectric material. The photosensitive adhesive can be a photoresist material suitable for a lithography process, such as polyacrylate photoresist capable of absorbing ultraviolet, or other photo-curing photoresist. Examples of the thermal-setting adhesive include epoxy resin or other thermally cross-linkable material compatible with the photosensitive adhesive. The dielectric material can be polyimide, silicon dioxide, silicon nitride or a combination thereof.

The semiconductor wafer of the present invention is, for example, a silicon wafer or an AsGa wafer. The wafer body has been formed with predetermined circuit layouts, and the first surface thereof is an inactive surface while the second surface thereof is an active surface having a plurality of electronic elements and circuits (not shown) disposed thereon. Alternatively, in another embodiment of the present invention, the semiconductor wafer is suitable for a multi-chip stacking application, such that each of the first and second surfaces of the wafer body is an active surface formed with predetermined circuit layouts and having electronic elements and circuits disposed thereon.

In the embodiment shown in FIG. 2, the semiconductor wafer 20 of the present invention further comprises the plurality of electrical connection pads 217 formed on the first surface 211 of the wafer body 215, and the protection layer 219 formed on the first surface 211 of the wafer body 215 and the plurality of electrical connection pads 217.

In order to electrically connect the semiconductor wafer to other electronic components such as a circuit substrate or another wafer, the protection layer on the wafer body can be formed with openings by various techniques to allow the electrical connection pads on the wafer body to be exposed. In an embodiment of the present invention, the material of the protection layer comprises, but not limited to, a photosensitive adhesive, a thermal-setting adhesive and a dielectric material. The photosensitive adhesive can be a photoresist material suitable for a lithography process, such as polyacrylate photoresist capable of absorbing ultraviolet, or other photo-curing photoresist. Thereby, the openings of the protection layer may be formed by the lithography process. Particularly, for example, if the photosensitive adhesive of the protection layer comprises a negative photoresist material, usually a photomask is used to cover areas predetermined for forming openings in the protection layer, and then exposure and development processes are performed, thereby obtaining the openings in the protection layer. As the protection layer of the present invention contains the photosensitive adhesive, adhesion of the protection layer can be enhanced when the lithography process is conducted, thereby making the protection layer strongly attached to the wafer surface. On the other hand, the technique for forming the openings of the protection layer is not limited to lithography, and laser or plasma etching can also be used to obtain the desirable openings.

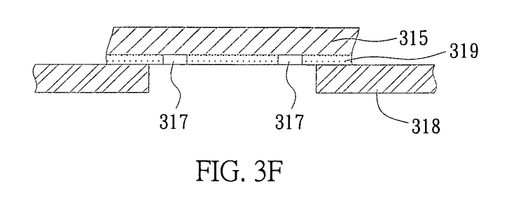

In the embodiment of having openings in the protection layer of the semiconductor wafer, the shape, area or height of the openings is not particularly limited. For example, if the thickness of the protection layer is equal to or slightly larger than the height of the electrical connection pads, the height of the openings in the protection layer is close to zero. In another case, to protect the electrical connection pads or allow the electrical connection pads to be strongly fixed to the wafer surface, the openings formed in the protection layer of the semiconductor wafer merely expose at least a part of each of the electrical connection pads. As shown in FIG. 3A, a protection layer 319 of a semiconductor wafer 30 is formed with a plurality of openings 312 each exposing at least a part of a corresponding one of electrical connection pads 317. In another embodiment, FIG. 3B shows that the respective protection layer 319 on a first surface 311 and a second surface 313 of the semiconductor wafer 30 is formed with a plurality of openings 312 each exposing a part of a corresponding one of the electrical connection pads 317.

For example, if the semiconductor wafer is used in subsequent window-type semiconductor packaging processes for forming a Window-Type Ball Grid Array (WBGA) semiconductor package, as shown in FIG. 3C, 3D or 3E, the protection layer 319 of the semiconductor wafer may comprise at least an opening 312 for exposing all the electrical connection pads 317, such that a plurality of bonding wires can be connected to the exposed electrical connection pads and pass through preformed holes in a circuit substrate to be electrically connected to bond pads of the circuit substrate. Similarly, the semiconductor wafer shown in FIGS. 3A and 3B or described in other embodiments of the present invention is also suitable for the WBGA semiconductor package. Referring to FIG. 3F for further describing the objective of the present invention, but not for limiting the scope of the present invention, with the protection layer 319 of the semiconductor wafer shown in FIG. 3E being exemplified here, the semiconductor wafer, after undergoing a cutting or singulation process, is mounted via its protection layer 319 to a package carrier 318. Moreover, besides for use in the WBGA package, the semiconductor wafer of the present invention is also applicable in a multi-chip stacking structure, wherein the protection layer of the semiconductor wafer can be used to attach another singulated wafer (chip).

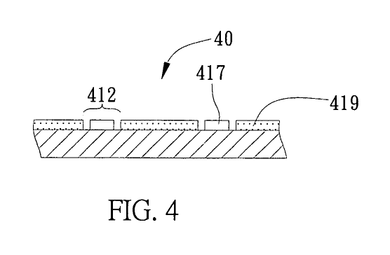

FIG. 4 is a cross-sectional schematic diagram showing a semiconductor wafer with an adhesive protection layer having openings according to another embodiment of the present invention. As shown in FIG. 4, the protection layer 419 of this semiconductor wafer 40 is formed with openings 412 by a conventional technique, and the openings 412 respectively expose top surfaces and side surfaces of electrical connection pads 417 of the semiconductor wafer 40.

The semiconductor wafer of the present invention may optionally comprise a removable cover layer disposed on the protection layer. The removable cover layer allows the semiconductor wafer to be easily packed and delivered while maintaining the satisfactory adhesion of the protection layer. By simply removing the removable cover layer, the semiconductor wafer is ready for subsequent fabrication processes. As the protection layer of the present invention comprises the photosensitive adhesive and the thermal-setting adhesive, it can be optionally subjected to thermal treatment or exposure in any stage of processes so as to allow the thermal-setting adhesive or photosensitive adhesive to become a b-stage adhesive, or even allow the entire protection layer to become b-stage. The extent of being partially cured (b-stage) depends on the material property or may be adjusted when necessary. Moreover, the protection layer can be processed before, during or after exposure of the photosensitive adhesive, to allow the protection layer or the thermal-setting adhesive or photosensitive adhesive in the protection layer to become a b-stage adhesive. Optionally, the protection layer can further be irradiated to have the photosensitive adhesive fully cured (c-stage). This not only enhances the adhesion of the protection layer but also structurally maintains the openings in the protection layer.

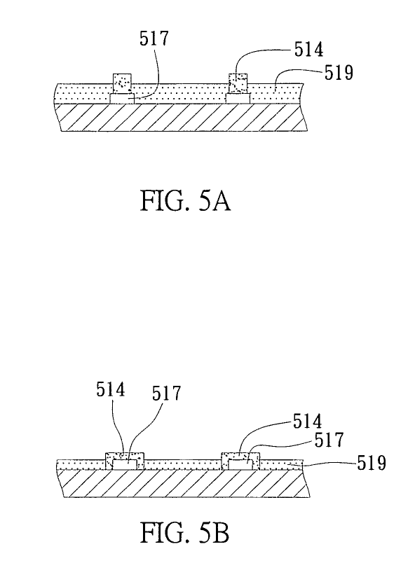

FIGS. 5A and 5B respectively show another semiconductor wafer 50 of the present invention, wherein a plurality of conductive bumps 514 are formed respectively on electrical connection pads 517 of the semiconductor wafer 50 by a well known technique. The conductive bumps 514 are used to protect the electrical connection pads 517 or provide greater electrical connection areas. In particular, as shown in FIG. 5B, the plurality of conductive bumps 514 may further cover side surfaces of the electrical connection pads 517. In this embodiment, the conductive bumps can be made of aluminum, copper, titanium, tin, lead, gold, bismuth, zinc, nickel, zirconium, magnesium, indium, antinomy, tellurium, or a combination thereof.

With the protection layer of the semiconductor wafer comprising the photosensitive adhesive, the thermal-setting adhesive and the dielectric material, the circuits and electrical connection pads formed on the wafer surface can be protected, and it is convenient to carry out a lithography process on the protection layer to expose the areas predetermined for electrical connection on the wafer, to be ready for subsequent processes such that attachment and establishing electrical connection, etc. This eliminates the need of applying an additional adhesive on a surface of the wafer for use in attachment, thereby greatly simplifying the proceeding of mounting the wafer to a circuit substrate during package fabrication processes, and also reducing the fabrication cost.

The present invention has been described using exemplary preferred embodiments. However, it is to be understood that the scope of the present invention is not limited to the disclosed arrangements. The scope of the claims, therefore, should be accorded the broadest interpretation, so as to encompass all such modifications and equivalents.

What is claimed is:

1. A semiconductor wafer with an adhesive protection layer, comprising:
a wafer body having a first surface and an opposing second surface;
a plurality of electrical connection pads formed on the second surface of the wafer body; and
the adhesive protection layer formed on the second surface of the wafer body and the plurality of electrical connection pads, wherein the protection layer is made of a material comprising a photosensitive adhesive, a thermal-setting adhesive and a dielectric material, and allows the semiconductor wafer being singulated to be mounted to a package carrier.

2. The semiconductor wafer of claim 1, wherein the first surface of the wafer body is an inactive surface and the second surface of the wafer body is an active surface formed with predetermined circuit layouts thereon.

3. The semiconductor wafer of claim 1, wherein each of the first and second surfaces of the wafer body is an active surface formed with predetermined circuit layouts thereon.

4. The semiconductor wafer of claim 3, further comprising: a plurality of electrical connection pads formed on the first surface of the wafer body; and another adhesive protection layer formed on the first surface of the wafer body and the plurality of electrical connection pads.

5. The semiconductor wafer of claim 1, wherein the protection layer further comprises a plurality of openings where at least a part of each of the electrical connection pads is exposed.

6. The semiconductor wafer of claim 1, wherein the protection layer further comprises at least an opening where all the electrical connection pads are exposed.

7. The semiconductor wafer of claim 6, wherein the opening of the protection layer exposes top surfaces and side surfaces of the electrical connection pads.

8. The semiconductor wafer of claim 1, which is a silicon wafer or an AsGa wafer.

9. The semiconductor wafer of claim 1, wherein the electrical connection pads are made of aluminum or copper.

10. The semiconductor wafer of claim 1, wherein the dielectric material is polyimide, silicon dioxide, silicon nitride, or a combination thereof.

11. The semiconductor wafer of claim 5, further comprising: a plurality of conductive bumps formed on the electrical connection pads respectively.

12. The semiconductor wafer of claim 7, further comprising: a plurality of conductive bumps formed on the electrical connection pads respectively and covering the side surfaces of the electrical connection pads.

13. The semiconductor wafer of claim 5, wherein the photosensitive adhesive of the protection layer is a cured photosensitive adhesive.

14. The semiconductor wafer of claim 1, further comprising: a removable cover layer disposed on the protection layer.

15. The semiconductor wafer of claim 11, wherein the conductive bumps are made of aluminum, copper, titanium, tin, lead, gold, bismuth, zinc, nickel, zirconium, magnesium, indium, antinomy, tellurium, or a combination thereof.
